(19) United States
(12) Patent Application Publication
(10) Pub. No.: US 2024/0061979 A1
(43) Pub. Date: Feb. 22, 2024

(54) DIFFERENTIABLE PARAMETRIC COMPUTER-ASSISTED DESIGN SOLUTION

(71) Applicant: NEURAL CONCEPT SA, Lausanne (CH)

(72) Inventors: Pierre BAQUÉ, St Sulpice (CH); Artem LUKOIANOV, Lausanne (CH); Jonathan DONIER, Rolle (CH); Théophile ALLARD, Genève (CH)

(21) Appl. No.: 18/270,835

(22) PCT Filed: Jan. 5, 2021
(86) PCT No.: PCT/IB2021/050039

§ 371 Date: Jul. 3, 2023

(51) Int. Cl. G06F 30/27; G06F 30/12

(52) U.S. Cl. CPC G06F 30/27; G06F 30/12

(57) ABSTRACT

A computer-implemented method is proposed in a computer-assisted design (CAD) system. In one embodiment, the method obtains gradients of an objective with respect to CAD parameters of a shape in a coordinate space, where the shape is obtained from the CAD parameters. The obtained gradients may then be used to modify the CAD parameters by applying a gradient descent algorithm aimed to maximise or minimise the objective. The present invention thus proposes a differentiable parametric CAD system comprising an artificial neural network, and which can be applied on top of any CAD software tool.

### TECHNICAL FIELD

The present invention relates to a method using gradients of an artificial neural network as proxies to compute the Jacobian of a parametric computer-assisted design (CAD) model. Thus, the proposed method can be used in the context of CAD models or tools. It can be used in the context of numerical optimisation of a CAD model to achieve some specific physics-based properties, such as minimising the drag of a car, or minimising the constraints related to an object, or an appearance aspect, such as matching a rendering given from a specific point of view, or reverse-engineering a design. The invention also relates to a computer program product and an apparatus or system with which the method can be implemented.

### BACKGROUND OF THE INVENTION

CAD tools and software make it possible for an engineer or a designer to create a three-dimensional (3D) shape via a computer interface. The CAD model is defined by a set of parameters that can vary, thereby producing a family of shapes. The CAD model can be converted into a mesh (surfacic or volumetric) or a point-cloud defining a shape via various tessellation, meshing or surface sampling methods. The operations for generating a CAD model from parameters and then a mesh or point cloud from CAD models are implemented as black-box functions in proprietary CAD software tools and/or meshing tools. However, these black boxes usually do not allow any information to be obtained on how modifying a given parameter would affect the shape (and more specifically, how it would affect the positions of each point in the mesh/point cloud) that is produced, without actually testing small perturbations of the model.

In the context of numerical optimisation of a CAD model to achieve some specific physics-based properties or an appearance aspect, it is necessary to know how parameter variations affect the positions of the points in the mesh/point cloud that is produced in order to implement a gradient-based optimisation, or sensitivity analysis on the CAD parameters, with respect to the properties of the mesh or point cloud. Indeed, once it is known how the parameters impact the shape, and in turn how the shape impacts the physical properties, such as a drag, constraints, etc. it is possible to deduce how the parameters impact the physical properties, and modify these parameters accordingly. It is thus assumed that it is known how the shape impacts the physical properties. It would therefore be important to obtain a method to calculate (or approximate) how the parameters impact the shape. However, currently available solutions have various drawbacks as explained further below.

More precisely, given an objective L, i.e. a scalar value which one aims to minimise (or to maximise), such as the drag of a car or the maximal structural constraint in an object, and given a sensitivity map dL/dXYZ (also called a gradient map or gradients, representing the direction and rate of fastest increase of L with respect to changes in XYZ) defined on the points of the shape (with coordinates or point positions XYZ), which describes how moving the positions of the points would affect the aforementioned objective, we want to calculate dL/dA (establishing how the CAD parameters impact the objective which one aims to minimise or maximise) which can be expressed as the matrix multiplication between dL/dXYZ and the Jacobian Matrix dXYZ/dA where “XYZ” are the coordinates of the points produced by the black-box function and “A” the vector of input CAD parameters of a CAD tool system that uses these CAD parameters to obtain XYZ. It is to be noted that the Jacobian matrix dXYZ/dA is only a property of the CAD parametrisation, and it does not depend on the specific task or objective.

It is to be noted that calculating the Jacobian matrix dXYZ/dA directly is sometimes not required. For example, if a neural network is used to calculate XYZ from A, a back-propagation algorithm can be used, which allows dL/dA to be directly calculated from dL/dXYZ without having to calculate dXYZ/dA. The back-propagation algorithm consists in applying a forward pass to the neural network inputs to obtain hidden activation values, followed by a backward pass which uses the hidden activation values to obtain gradients with respect to the neural network inputs (e.g. dL/dA) from gradients with respect to its outputs (e.g. dL/dXYZ). In what follows we will refer to Jacobian function J to describe the function that allows dL/dA to be calculated from dL/dXYZ, i.e. the function that is applied in the backward pass.

Existing solutions rely on the approaches briefly described below.

In some cases, the parametrisation can be handcrafted in a way that makes the computation of the Jacobian easily implementable, such as disclosed in a publication entitled “CAD-Based Optimization of a Race Car Front Wing” by Ilya Tolchinsky et al., SAE Int. J. Adv. & Curr. Prac. in Mobility 2(3):1422-1428, 2020. However, this solution has the main shortcomings that it is time and resource consuming to implement it for every new case, and it is not feasible for all problems.

One can rely on control points or free-form parametrisations, which makes the computation of the Jacobian easily implementable. This kind of solution is discussed in a publication entitled “Free-form-deformation parameterization for multilevel 3D shape optimization in aerodynamics” by Michele Andreoli et al., Théme 4—Simulation et optimisation de systemes complexes, Projet Opale, Rapport de recherche no 5019—November 2003. However, free-form deformation of control points or other “morphing-based” methods do not allow implicit constraints embedded into the parametrisation of the CAD model to be respected. Furthermore, it is often not possible to reconstruct a CAD model based on a morphed mesh model. This is a major issue in practice because CAD models are the format used as reference design formats in the industry.

Solutions, such as the one disclosed in a publication entitled “Towards the Automatic Differentiation of a CAD System” by Mladen Banovic, Institut für Mathematik Universitet Paderborn, 19th EuroAD Workshop Kaiserslautern, Germany April 2016, which rely on automatic differentiation frameworks make it possible to compute the gradients of a specifically defined parametrisation. These kinds of solutions have the disadvantage that automatic differentiation is restricted to a specific set of operations and it is very difficult to implement a fully general-purpose CAD software tool based on automatic differentiation.

It is possible to approximate the gradients locally using finite differences. This kind of approach is disclosed in a publication entitled “Gradient-based Optimization of Parameterized CAD Geometries” by Timothée Leblond et al., 11th World Congress on Structural and Multidisciplinary Optimization, 7th-12th, June 2015, Sydney Australia. However, this approach has the drawback that it is very costly to use finite differences for high-dimensional parametrisations. Furthermore, the convergence properties of an optimisation run with this approach are very bad.

In specific cases, differentiable CAD software can be developed, such as disclosed in a publication entitled “Survey of Shape Parameterization Techniques for High-Fidelity Multidisciplinary Shape Optimization” by Jamshid A. Samareh, published Online: 17, May 2012. The differentiable CAD software tools are necessarily different from the mainstream software tools, which companies use in production. These solutions remain marginal and are limited to research purposes.

### SUMMARY OF THE INVENTION

It is an object of the present invention to overcome at least some of the problems identified above. Thus, the invention aims to provide a solution for computing the Jacobian of a parametric computer-aided or computer-assisted design (CAD) model and/or numerically optimising a CAD model.

According to a first aspect of the invention, there is provided a computer-implemented method for obtaining gradients of an objective with respect to CAD parameters of a shape in a coordinate space as recited in claim 1.

The present invention thus proposes a differentiable parametric CAD system comprising an artificial neural network, which can be applied on top of any CAD software tool. It brings the best of both worlds where people can both use their favourite CAD software and obtain (approximate) gradients for it. In other words, the invention combines the benefits of CAD tools, but which do not compute any gradients on the one hand, and the computation of gradients of shape point positions with respect to the CAD parameters used to obtain the shape on the other hand.

According to a second aspect of the invention, there is provided a non-transitory computer program product comprising instructions for implementing the steps of the method according to the first aspect of the present invention.

According to a third aspect of the invention, there is provided an apparatus or system configured to carry out the method according to the first aspect of the present invention.

According to a fourth aspect of the invention, there is provided a computer-implemented method for obtaining gradients of shape point positions representing a shape in a coordinate space with respect to CAD parameters used for obtaining the shape as recited in claim 21.

Other aspects of the invention are recited in the dependent claims attached hereto.

### BRIEF DESCRIPTION OF THE DRAWINGS

Other features and advantages of the invention will become apparent from the following description of non-limiting example embodiments, with reference to the appended drawings, in which:

FIG. 1 is a simplified block diagram schematically illustrating a system where the teachings of the present invention may be applied;

FIG. 2 schematically illustrates the training phase of the artificial neural network used in the system of FIG. 1;

FIG. 3 shows the inputs and output of the artificial neural network during the training phase;

FIG. 4 is a flow chart illustrating an example method according to a first embodiment of the present invention;

FIG. 5 is a flow chart illustrating forward and backward passes of the artificial neural network during inference in more detail; and

FIG. 6 is a flow chart illustrating an example method according to a second embodiment of the present invention.

### DETAILED DESCRIPTION OF EMBODIMENTS OF THE INVENTION

Some embodiments of the present invention will now be described in detail with reference to the attached figures. The first embodiment is described in the context of determining gradients of an objective with respect to the CAD parameters that are used to obtain a given shape. The gradient of a scalar-valued differentiable function denotes the direction of greatest change of the scalar function. The objective is a scalar to be minimised (or maximised), such as the drag of a car or an aircraft wing or the maximal constraint of an object. The objective may also relate to at least one of the following: aerodynamics, pressure, velocity, structural mechanics, displacement, and stress related to an object. However, the teachings of the present invention are not limited to this context. The present description refers to point clouds on several occasions, which are to be interpreted broadly in the present context. The meaning of “point clouds” is to be understood to be a set of points in an N-dimensional space, where N may be any positive integer depending on the application. Meshes differ from point clouds in that meshes, in addition to points, also comprise connections between points in the point space. Furthermore, the words “point cloud” and “set of points” may often be used interchangeably. Identical or corresponding functional and structural elements which appear in the different drawings are assigned the same reference numerals.

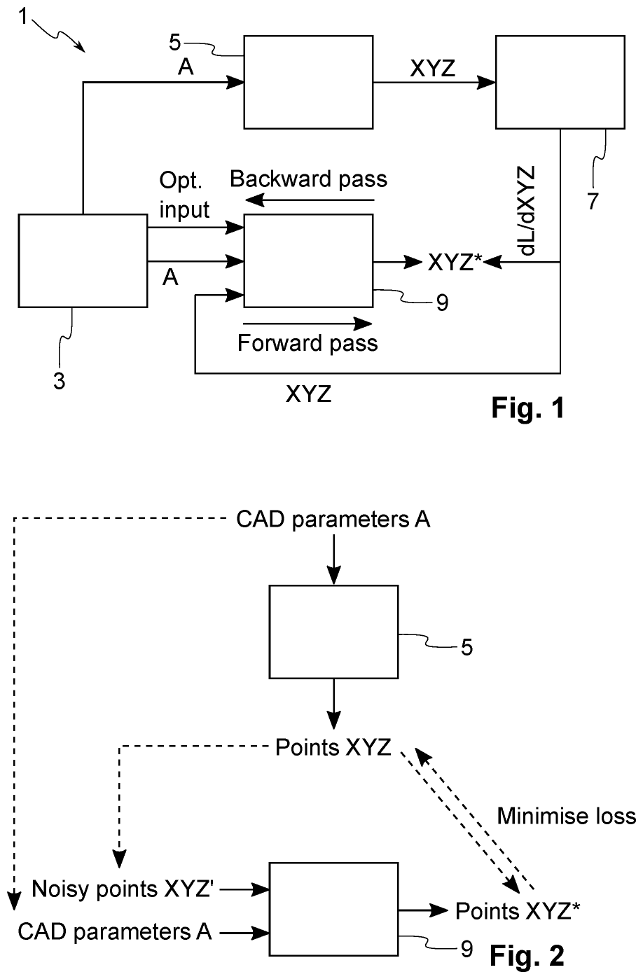

FIG. 1 illustrates in a simplified manner a shape planning system 1 or a shape design system, where the teachings of the present invention can be applied. The system comprises an input unit or element 3 configured to receive CAD parameters or alternatively, the input unit 3 is configured to generate the CAD parameters. The system 1 also comprises a CAD tool system 5 that is configured to receive the CAD parameters and to use these CAD parameters to generate a geometry or shape, defined by a set of shape point positions or coordinates XYZ, i.e. a point cloud, or more preferably a mesh, in a given space (or coordinate system), such as a three-dimensional space. The CAD parameters from the input unit 3 thus serve as an input to the CAD tool system 5, which comprises a CAD tool and also optionally a meshing tool. It is to be noted that CAD tool is here understood in a broad sense, i.e. any non-differentiable tool, function, API, etc. that produces or modifies a shape from parameters, such parameters being referred to as CAD parameters. A sensitivity map generator 7 is also provided, and it is configured to use the generated shape or more preferably the mesh from the CAD tool system 5 to generate an objective L, which is a scalar (i.e. a quantity having only magnitude, but no direction). It is to be noted often the sensitivity map generator 7 needs a mesh and not just a point cloud to generate the objective L. In this case the CAD tool system 5 would also return the adjacency information between the points (i.e. how they are connected with each other). In other words, the CAD tool system 5 may provide an additional input to the sensitivity map generator 7, which is the adjacency information of the mesh. It is to be noted that the adjacency information may take several forms. For example, it could be an adjacency matrix (i.e., a list of neighbours for each point), a list of faces (i.e., the sets of points that compose the faces of the mesh), etc. Subsequently, only the gradients dL/dXYZ, as explained later, are obtained and needed, since the adjacency is not differentiable. The sensitivity map generator 7 is also configured to generate gradients or derivatives of the objective with respect to the shape or more precisely with respect to its point positions XYZ. In other words, the sensitivity map generator is configured to generate a sensitivity map or gradient map defined on the points or vertices of the shape, which in turn is defined by a mesh or point cloud. These gradients are also in the present description referred to as first gradients dL/dXYZ.

The system 1 further comprises an artificial intelligence system or differentiable regression algorithm 9, which in the present example embodiments is an artificial neural network (ANN), and more specifically a convolutional neural network (CNN). Convolutional networks can be considered neural networks that use convolution (which is a linear operation) in place of general matrix multiplication in at least one of their layers. A CNN comprises an input layer and an output layer, as well as multiple hidden layers. The hidden layers of a CNN typically comprise a series of convolutional layers that convolve with a multiplication or other dot product. The activation function is typically a rectifier linear unit, and is subsequently followed by additional layers, such as pooling layers, fully connected layers and normalisation layers. The ANN 9 is configured to generate, once trained, in a backward pass gradients or derivatives of the neural network outputs with respect to the CAD parameters, which are used to obtain the shape point positions XYZ by the CAD tool system 5. These gradients are also in the present description referred to as dF/dA. The gradients dF/dA are then used as an approximation of the Jacobian dXYZ/dA (i.e. the gradients of the black-box function, in other words the CAD tool system). Alternatively, or in addition, the ANN is configured to generate, once trained, in a backward pass, the gradients of the objective with respect to the CAD parameters from the first gradients dL/dXYZ of the objective with respect to the shape point positions by applying its jacobian function J* to the first gradients, where the Jacobian function J* is the neural network approximation of the true Jacobian function J. The outputs of the jacobian function of the neural network J* applied to dL/dXYZ are then used as an approximation of the outputs of the jacobian function J applied to dL/dXYZ. The gradients of the objective with respect to the CAD parameters are also in the present description referred to as second gradients dL/dA.

The present invention is based on an idea of using the trained neural network F(A) that takes as input the CAD parameters A, optionally modified by a constant or variable, collectively forming a first set of inputs, along with the shape point positions XYZ forming a second set of inputs, and optionally a third set of inputs, which would correct the effect of the modification of the CAD parameters. The ANN 9 is trained to output the corresponding shape point positions or coordinates XYZ, although in practice, the neural network outputs approximate or predicted shape point positions XYZ*. It then uses its gradients dF/dA, as an approximation of the Jacobian dXYZ/dA, or alternatively its jacobian function J* as an approximation of the jacobian function J. The ANN 9 can then obtain the second gradients dL/dA by multiplying the first gradients dL/dXYZ with the gradients dXYZ/dA, or by applying the jacobian function J* to dL/dXYZ. The second gradients can then be used for numerical optimisation via gradient-based optimisation or related methods.

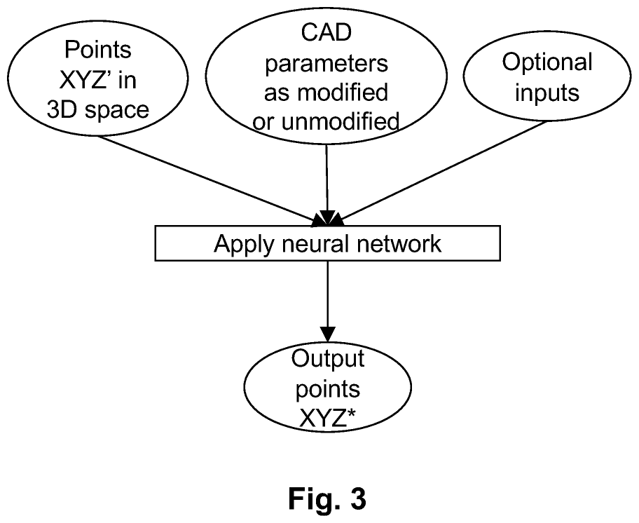

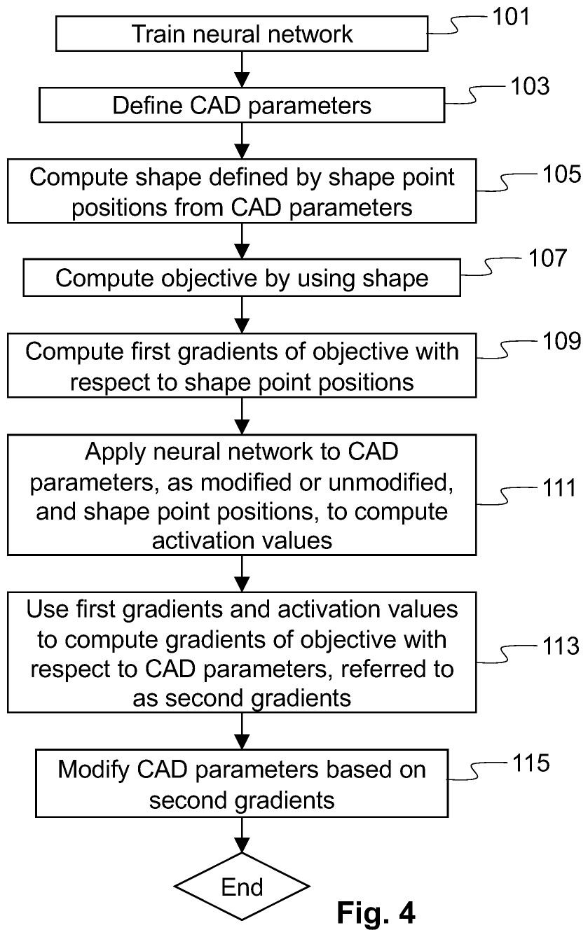

Before taking advantage of the gradients as computed according to the present invention, the ANN 9 is first trained with the aim that it produces shape point positions XYZ (optionally modified by a constant or variable) from a first set of inputs comprising the CAD parameters A, which are also optionally modified, and a second set of inputs comprising point positions XYZ′, and optionally a third set of inputs. Here, the point positions XYZ′ may be understood to be a noisy representation of the shape point positions XYZ. In other words, the point positions XYZ′ do not typically belong or represent the shape. It is to be noted that the point positions XYZ′ may even be random points in the coordinate space. The training phase is illustrated in FIGS. 2 and 3. The ANN 9 is thus trained to project point positions XYZ′ in 3D space onto a shape, given its CAD parameters. More precisely, for a given point position xyz′ (which typically does not belong to the shape), the ANN 9 is requested to output the closest point xyz on the surface of the shape. The training set consists of elements containing: (i) the training CAD parameters of a shape, (ii) a first set of N points in 3D space, and (iii) a second set of N corresponding points that belong to the shape (typically, the closest points on the shape to each of the N points in the first set). The ANN 9 is then provided with the training CAD parameters and the first set of points and is trained to output the second set of points. FIG. 2 illustrates an example training process where the second set of points is produced directly by the CAD software and the first set of points is a noisy representation of these points, obtained by adding some (well-chosen) noise to the points in the second set of points. However, the first and second sets of points could be obtained differently. One possibility is to include in the first set of points some points obtained independently of the CAD tool system 5 (e.g. selected randomly in 3D space), then calculate their projections on the shape produced by the CAD software and use these projections in the second set of points. Then, at inference time, the CAD tool system 5 is used to generate the points XYZ (the first forward pass) from the CAD parameters A, and the ANN 9 is used to obtain the second gradients. This gives the best of both worlds, with an exact generation of the shapes with CAD and the differentiability of the ANN that allows approximate gradients to be obtained.

During training, the ANN 9 is typically trained by using a large set of training CAD parameters, which may be understood as first CAD parameters or a first set of CAD parameters, such that respective training CAD parameters in the set are associated with or used for obtaining respective training shape point positions. The ANN is then trained to output respective training shape point positions when the ANN is applied to the associated training CAD parameters, as modified or unmodified, and to point positions, which typically do not represent any given shape, and optionally to a third set of inputs. The ANN 9 may also be trained to project point positions associated with a first set of training CAD parameters onto a respective shape obtained from a second set of training CAD parameters, thereby producing projections of the point positions, and wherein, during training, the ANN 9 is given as inputs, in addition to the point positions, the first set of training CAD parameters and training shape parameters, which are equal to the difference between the values of the second set of training CAD parameters and the first set of training CAD parameters, and optionally a third set of inputs. Note that the large set of training CAD parameters does not necessarily include the CAD parameters, which may be understood as second CAD parameters or a second set of CAD parameters, which are later used for inference. Ideally (however not necessarily), the CAD parameters which are used for inference should be included in or they should not be too different from some elements of the large set of training CAD parameters.

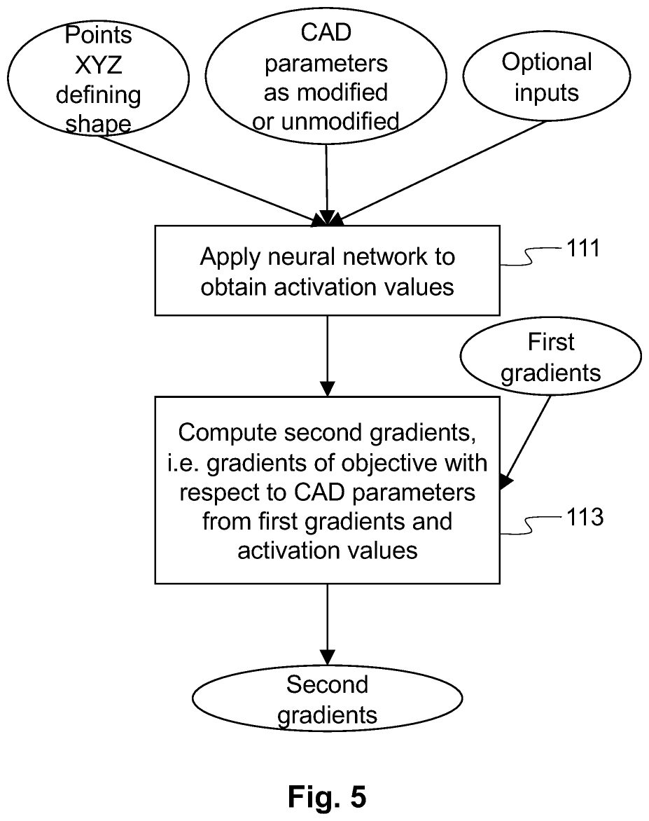

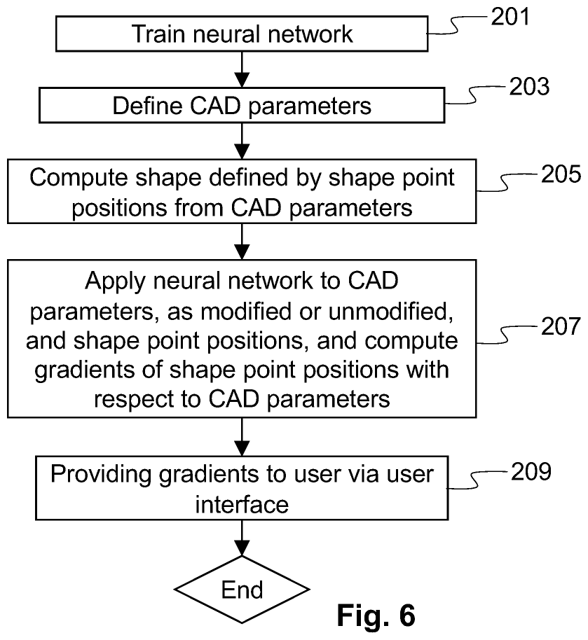

The first embodiment of the invention is next explained in more detail with reference to the flow charts of FIGS. 4 and 5. In step 101, the ANN 9 is trained as was explained above. As was explained above, this step involves feeding point positions together with at least respective training shape parameters (here the word “together” does not necessarily mean that the inputs are fed simultaneously) into the ANN 9 to project the point positions onto a respective shape obtained from respective training CAD parameters to thereby produce respective predicted shape point positions as modified or unmodified as an output of the ANN 9, where the respective training shape parameters are equal to the respective training CAD parameters as modified or unmodified. The training shape parameters may be understood as first shape parameters or a first set of shape parameters. Once trained, the ANN is thus able to project points in 3D space onto a shape defined by some given CAD parameters. In step 103, the CAD parameters A are generated or defined. These parameters may for instance be given by the user of the system 1 or they may be generated by the input unit 3. This step may also involve feeding the CAD parameters to the CAD tool system 5, which in step 105 generates or computes the geometry or shape by using the CAD parameters. The shape is defined by a set of shape point positions XYZ and also preferably by the adjacency information between the points. The points XYZ are thus associated with the CAD parameters that were used to obtain the shape. Step 105 may also involve feeding the generated shape point positions XYZ, optionally including the adjacency information, to the sensitivity map generator 7.

In step 107, the sensitivity map generator 7 determines or generates an objective based on the shape generated by the CAD tool system 5. The objective may be generated from physical properties, such as the drag of an object (e.g. a car or aircraft), or the maximum mechanical constraint under pre-defined forces, that depend on the shape. The objective is a function to be minimised or maximised. It is to be noted that the sensitivity map generator 7 could take other inputs in addition to the shape, for example input scalars representing the conditions to which the shape is subject to, such as the velocity of the wind around the shape. In step 109, the sensitivity map generator 7 then generates the gradients of this objective with respect to the shape. In other words, in this step, the first gradients dL/dXYZ are computed, which thus form the sensitivity map of the objective with respect to the shape. The first gradients may be generated using an adjoint method or a surrogate model method. The surrogate model may be an artificial neural network that was trained to approximate a simulator. The adjoint method is a numerical approach to compute the gradients of a partial differential equation, as used in a typical physics solver.

In step 111, shape parameters, which may be understood as second shape parameters or a second set of shape parameters, and which in this example are the CAD parameters, as modified or unmodified (forming first inputs), and the shape point positions XYZ (forming second inputs) are fed into the ANN 9, which thus uses these inputs to determine hidden activation values to be used when applying the jacobian function J* to the sensitivity map. The shape parameters may or may not be a subset of the training shape parameters. Optionally, third inputs may also be fed into the ANN 9. The third inputs may comprise parameters (also referred to as compensation parameters) that compensate for the shape parameters when they are not equal to the unmodified CAD parameters. For example, if the shape parameters take zero values or substantially zero values, then the trained ANN 9 is further applied to the compensation parameters to compensate for the shape parameters, and wherein the compensation parameters are equal or substantially equal to the CAD parameters.

Step 111 is thus part of the inference process to calculate the Jacobian or alternatively the hidden activation values to be used when applying the Jacobian function J*, for the given shape defined by the CAD parameters A. To achieve this, the ANN 9 is evaluated on these CAD parameters and on the points XYZ at which we want to calculate the gradients (obtained from the CAD tool system). The output XYZ* of the ANN 9 is of no interest in itself (since it is supposed to be equal to XYZ, as the points XYZ already belong to the shape). It is to be noted that step 111 forms the forward pass operation of the ANN 9, and a set of predicted shape point positions XYZ* is thus obtained at the output of the ANN. The projected predicted shape point positions XYZ* may be absolute predicted shape point positions in the coordinate space, or alternatively the projections generated by the ANN 9 are relative predicted shape point positions in the coordinate space with respect to the shape point positions as fed into the ANN 9.

In step 113, the ANN 9 generates gradients of the objective with respect to the CAD parameters dL/dA from the first gradients and the Jacobian or by applying the Jacobian function J* to the first gradients. The gradients computed in this step are referred to as second gradients. In other words, the sensitivity map, and in particular the point positions XYZ and the associated sensitivities, obtained in step 109, are used in this step to obtain the second gradients. It is to be noted that step 113 forms the backward pass operation of the ANN 9. In other words, in this step, the first gradients are backpropagated to the neural network inputs. It is to be further noted that the neural network outputs XYZ* of the forward pass are ignored in the process, as the process relies on the backward pass to obtain the second gradients. The flow chart of FIG. 5 summarises steps 111 and 113. In step 115, the CAD parameters can then optionally be modified or updated by using the second gradients. The CAD parameters may be modified by applying a gradient descent algorithm aimed to maximise or minimise the objective. The gradient descent algorithm may involve adding or subtracting the second gradients, optionally multiplied by a scaling factor, from the CAD parameters. The method may also optionally comprise the step(s) of processing one or more of the gradient values and/or gradient variables, and/or displaying them to a user via a user interface. The gradient values and/or gradient variables may instead be provided to the user through an application programming interface. The word “provide” is understood to also cover the action of displaying the gradients to the user.

The flow chart of FIG. 6 illustrates the second embodiment of the present invention. In step 201, the neural network is trained as explained above. In step 203, the CAD parameters are defined or generated for a given shape. This step is thus identical or substantially identical to step 103. In step 205, in this example, the CAD tool system 5 generates or computes the geometry or shape by using the CAD parameters. The shape is defined by a set of shape point positions XYZ, which are thus associated with the CAD parameters that were used to obtain the shape. This step is thus identical or substantially identical to step 105. However, it is not mandatory that the CAD tool system generates the shape point positions. For example, the shape point positions may be received from the user.

In step 207, shape parameters, which in this example are the CAD parameters, as modified or unmodified (forming first inputs), and the shape point positions XYZ (forming second inputs) are fed into the ANN 9, which thus uses these inputs to determine gradients of the shape point positions with respect to the CAD parameters (as modified or unmodified) dXYZ/dA. Optionally, third inputs may also be fed into the ANN 9. The third inputs may comprise parameters (also referred to as compensation parameters) that compensate for the shape parameters when they are not equal to the unmodified CAD parameters. This step is thus part of the inference process to calculate the Jacobian for the given shape defined by the CAD parameters A. To achieve this, the ANN 9 is evaluated on these CAD parameters and on the points XYZ at which we want to calculate the gradients (obtained from the CAD tool system). The output XYZ* of the ANN 9 is of no interest in itself (since it is supposed to be equal to XYZ, as the points XYZ already belong to the shape). However, the additional information which the ANN 9 provides is the gradient of these outputs with respect to the CAD parameters, i.e. where the points would move if the CAD parameters were modified, which is what we were looking for. Step 207 forms the forward and backward pass operation of the ANN 9, and a set of predicted shape point positions XYZ* is thus obtained at the output of the ANN. The projected predicted shape point positions XYZ* may be absolute predicted shape point positions in the coordinate space, or alternatively the projections generated by the ANN 9 are relative predicted shape point positions in the coordinate space with respect to the shape point positions as fed into the ANN 9.

In step 209, the gradients obtained in step 209 are provided (by e.g. displaying them) to the user via a user interface, which may be a display or an application programming interface (API). Instead of displaying these gradients, or in addition to it, these gradients may be sent in a desired file format to the user or stored locally or in a cloud computing environment. The second embodiment thus differs from the first embodiment in that no first and second gradients are generated according to the second embodiment. Furthermore, in the second embodiment, gradients dXYZ/dA are generated directly. However, the rest of the above teachings apply also to the second embodiment. The second embodiment also covers a corresponding apparatus or system, and a computer program product configured, or comprising means to carry out the method according to the second embodiment of the present invention.

The second embodiment can be thus summarised as a computer-implemented method for obtaining gradients of shape point positions representing a shape in a coordinate space with respect to CAD parameters used for obtaining the shape, the method comprising:
training 201 an artificial neural network 9 to project point positions when fed also with at least training shape parameters into the artificial neural network 9 onto a respective shape obtained from respective training CAD parameters to thereby produce respective predicted shape point positions as modified or unmodified as an output of the artificial neural network 9, the training shape parameters being equal to the training CAD parameters as modified or unmodified;
obtaining 205 the shape point positions in the coordinate space;
applying 207 the trained artificial neural network 9 to at least the shape point positions and shape parameters to obtain gradients of the shape point positions with respect to the shape parameters, the shape parameters being equal to the CAD parameters as modified or unmodified; and
providing 209 the gradients to a user or returning the gradients to a program.

The method may further comprise generating 103 the CAD parameters or receiving them from the user.

The shape parameters may be equal to the CAD parameters.

The shape point positions may be obtained from the CAD parameters using a CAD tool system 5.

The artificial neural network 9 may be trained by feeding the point positions together with the respective training CAD parameters, as modified or unmodified, into the artificial neural network 9.

The trained artificial neural network 9 may further be applied to compensation parameters to compensate for the shape parameters when they are equal to the modified CAD parameters.

The shape parameters may take zero values or substantially zero values, and the trained artificial neural network 9 may further be applied to compensation parameters to compensate for the shape parameters, wherein the compensation parameters may be equal or substantially equal to the CAD parameters.

The artificial neural network 9 may be trained to project the point positions onto the respective shape thereby producing projections of the point positions.

The artificial neural network 9 may be trained to project the point positions associated with a first set of training CAD parameters onto a respective shape obtained from a second set of training CAD parameters, thereby producing projections of the point positions, and, during training, the artificial neural network (9) may be given as inputs the point positions, the first set of training CAD parameters and training shape parameters equal to the difference between values of the second set of training CAD parameters and the first set of training CAD parameters, or the artificial neural network 9 may be given as inputs the point positions, the second set of training CAD parameters and training shape parameters equal to the difference between values of the first set of training CAD parameters and the second set of training CAD parameters.

The projections generated by the trained artificial neural network 9 may be absolute predicted shape point positions in the coordinate space.

The projections generated by the trained artificial neural network 9 may be relative predicted shape point positions in the coordinate space with respect to the point positions and/or shape point positions as fed into the artificial neural network 9.

The coordinate space may be a two-dimensional or a three-dimensional coordinate space.

A non-transitory computer program product may be provided in connection with the second embodiment, the product comprising instructions for implementing the steps of the method when loaded and run on computing means of a computing device 1.

A computer-assisted design system 1 may also be provided in connection with the second embodiment for obtaining gradients of shape point positions representing a shape in a coordinate space with respect to CAD parameters used for obtaining the shape, wherein the system is configured to carry out the method according to the second embodiment.

The above-described method according to the first and second embodiments may be carried out by suitable circuits or circuitry, which are part of the CAD tool system and the ANN 9. The terms “circuits” and “circuitry” refer to physical electronic components or modules (e.g. hardware), and any software and/or firmware (“code”) that may configure the hardware, be executed by the hardware, and or otherwise be associated with the hardware. The circuits may thus be configured or operable to carry out or they comprise means for carrying out the required method as described above.

While the invention has been illustrated and described in detail in the drawings and foregoing description, such illustration and description are to be considered illustrative or exemplary and not restrictive, the invention being not limited to the disclosed embodiment. Other embodiments and variants are understood, and can be achieved by those skilled in the art when carrying out the claimed invention, based on a study of the drawings, the disclosure and the appended claims. Further variants of the present invention may be obtained by combining any of the above teachings.

In the claims, the word “comprising” does not exclude other elements or steps, and the indefinite article “a” or “an” does not exclude a plurality. The mere fact that different features are recited in mutually different dependent claims does not indicate that a combination of these features cannot be advantageously used. Any reference signs in the claims should not be construed as limiting the scope of the invention.

1. A computer-implemented method for obtaining gradients of an objective with respect to computer-assisted design (“CAD”) parameters of a shape in a coordinate space, the method comprising:
training an artificial neural network to project point positions when fed with at least training shape parameters into the artificial neural network onto a respective shape obtained from respective training CAD parameters to thereby produce respective predicted shape point positions as modified or unmodified as an output of the artificial neural network, the training shape parameters being equal to the training CAD parameters as modified or unmodified;
obtaining shape from the CAD parameters using a CAD tool system, the shape being at least partially defined by shape point positions in the coordinate space;
obtaining gradients of the objective with respect to the shape point positions, referred to as first gradients;
applying the trained artificial neural network in a forward pass to at least the shape point positions and shape parameters to obtain activation values of the artificial neural network, the shape parameters being equal to the CAD parameters as modified or unmodified; and
applying the trained artificial neural network in a backward pass to at least the first gradients using the activation values to obtain gradients of the objective with respect to the CAD parameters, referred to as second gradients.

2. The method according to claim 1, wherein the objective is a function to be minimized or maximized.

3. The method according to claim 1, wherein the method further comprises calculating the objective using a physical simulation or a surrogate model of a physical simulation.

4. The method according to claim 1, wherein the method further comprises at least one of generating the CAD parameters and receiving them from a user.

5. The method according to claim 1, wherein the first gradients are obtained using a method selected from the group consisting of an adjoint method, a surrogate model method, and combinations thereof.

6. The method according to claim 5, wherein the surrogate model is another artificial neural network.

7. The method according to claim 1, wherein the shape parameters are equal to the CAD parameters.

8. The method according to claim 1, wherein the artificial neural network is trained by feeding the point positions together with the respective training CAD parameters, as modified or unmodified, into the artificial neural network.

9. The method according to claim 1, wherein the trained artificial neural network is further applied to compensation parameters to compensate for the shape parameters when they are equal to the modified CAD parameters.

10. The method according to claim 1, wherein the shape parameters take zero values or substantially zero values, and wherein the trained artificial neural network is further applied to compensation parameters to compensate for the shape parameters, and wherein the compensation parameters are equal or substantially equal to the CAD parameters.

11. The method according to claim 1, wherein the artificial neural network is trained to project the point positions onto the respective shape thereby producing projections of the point positions.

12. The method according to claim 1, wherein the artificial neural network is trained to project the point positions associated with a first set of training CAD parameters onto a respective shape obtained from a second set of training CAD parameters, thereby producing projections of the point positions, and wherein, during training, the artificial neural network is given as inputs the point positions, the first set of training CAD parameters and training shape parameters equal to the difference between values of the second set of training CAD parameters and the first set of training CAD parameters, or the artificial neural network is given as inputs the point positions, the second set of training CAD parameters and training shape parameters equal to the difference between values of the first set of training CAD parameters and the second set of training CAD parameters.

13. The method according to claim 1, wherein the projections generated by the trained artificial neural network are absolute predicted shape point positions in the coordinate space.

14. The method according to claim 1, wherein the projections generated by the trained artificial neural network are relative predicted shape point positions in the coordinate space with respect to at least one of the point positions and/or the shape point positions as fed into the artificial neural network.

15. The method according to claim 1, wherein the method further comprises using (115) the second gradients to modify the CAD parameters by applying a gradient descent algorithm aimed to at least one of maximize and minimize the objective.

16. The method according to claim 15, wherein the gradient descent algorithm involves at least one of adding and subtracting the second gradients multiplied by a scaling factor from the CAD parameters.

17. The method according to claim 1, wherein the second gradient values are returned to a user through an application programming interface.

18. The method according to claim 1, wherein the coordinate space is at least one of a two-dimensional and a three-dimensional coordinate space.

19. A non-transitory computer program product comprising instructions for implementing a plurality of steps when loaded and run on computing means of a computing device, the plurality of steps related to a computer-implemented method for obtaining gradients of an objective with respect to computer-assisted design (“CAD”) parameters of a shape in a coordinate space, the plurality of steps comprising:
training an artificial neural network to project point positions when fed with at least training shape parameters into the artificial neural network onto a respective shape obtained from respective training CAD parameters to thereby produce respective predicted shape point positions as modified or unmodified as an output of the artificial neural network, the training shape parameters being equal to the training CAD parameters as modified or unmodified;
obtaining a shape from the CAD parameters using a CAD tool system, the shape being at least partially defined by shape point positions in the coordinate space;
obtaining gradients of the objective with respect to the shape point positions, referred to as first gradients;
applying the trained artificial neural network in a forward pass to at least the shape point positions and shape parameters to obtain activation values of the artificial neural network, the shape parameters being equal to the CAD parameters as modified or unmodified; and
applying the trained artificial neural network in a backward pass to at least the first gradients using the activation values to obtain gradients of the objective with respect to the CAD parameters, referred to as second gradients.

20. A computer-assisted design (“CAD”) system for obtaining gradients of an objective with respect to CAD parameters of a shape in a coordinate space, the system configured to perform operations comprising:
training an artificial neural network to project point positions when fed also with at least training shape parameters into the artificial neural network onto a respective shape obtained from respective training CAD parameters to thereby produce respective predicted shape point positions as modified or unmodified as an output of the artificial neural network, the training shape parameters being equal to the training CAD parameters as modified or unmodified;
obtaining a shape from the CAD parameters using a CAD tool system, the shape being at least partially defined by shape point positions in the coordinate space;
obtaining gradients of the objective with respect to the shape point positions, referred to as first gradients;
applying the trained artificial neural network in a forward pass to at least the shape point positions and shape parameters to obtain activation values of the artificial neural network, the shape parameters being equal to the CAD parameters as modified or unmodified; and
applying the trained artificial neural network in a backward pass to at least the first gradients using the activation values to obtain gradients of the objective with respect to the CAD parameters, referred to as second gradients.

21. A computer-implemented method for obtaining gradients of shape point positions representing a shape in a coordinate space with respect to computer-assisted design (“CAD”) parameters used for obtaining the shape, the method comprising:
training an artificial neural network to project point positions when fed with at least training shape parameters into the artificial neural network onto a respective shape obtained from respective training CAD parameters to thereby produce respective predicted shape point positions as modified or unmodified as an output of the artificial neural network, the training shape parameters being equal to the training CAD parameters as modified or unmodified;
obtaining shape point positions in the coordinate space;
applying the trained artificial neural network to at least the shape point positions and shape parameters to obtain gradients of the shape point positions with respect to the shape parameters, the shape parameters being equal to the CAD parameters as modified or unmodified; and
providing the gradients to a user or returning the gradients to a program.

22. The method according to claim 21, wherein the gradients are provided to the user via a user interface, via an application programming interface, stored via at least one selected from the group consisting of in a cloud computing environment, locally in a computing device, saved in a file, and combinations thereof.
